(19) United States
(12) Patent Application Publication
(10) Pub. No.: US 2003/0217812 A1
(43) Pub. Date: Nov. 27, 2003

(54) Plasma etching equipment and method for manufacturing semiconductor device

(75) Inventors: Takahiro Yoshiki, Tokyo (JP); Kenji Kawai, Tokyo (JP)

Correspondence Address: Leydig ,Voit & Mayer, 700 Thirteenth Street N.W., Suite 300, Washington, DC, 20005-3960, US

(73) Assignee: MITSUBISHI DENKI KABUSHIKI KAISHA

(21) Appl. No.: 10/359,164

(22) Filed: Feb. 6, 2003

(30) Foreign Application Priority Data
May 21, 2002 (JP) 2002-146828

(51) Int. Cl. H01L 21/306; C23F 1/00

(52) U.S. Cl. 156/345.41; 156/345.43; 156/345.47

(57) ABSTRACT

A parallel flat plate type plasma etching equipment can supply RF to both the upper electrode 14 and the lower electrode 18. In the plasma etching equipment a metal plate 31 having a ground potential, and having a plurality of openings H in the range of a predetermined area is installed between the upper electrode 14 and the wafer 16 placed on the lower electrode 18. A plasma etching equipment comprises a lower electrode supplied with a high-frequency power and a microwave-introducing window in the location facing said lower electrode. In the plasma etching equipment a metal plate 32 has a ground potential, and has a plurality of openings H in the range of a predetermined area. The metal plate 32 is installed between the microwave-introducing window 26 and the wafer 16 placed on the lower electrode 18.

### BACKGROUND OF THE INVENTION

1. Field of the Invention

The present invention relates to a plasma etching equipment, and a method for manufacturing a semiconductor device using the plasma etching equipment; and more specifically to a parallel flat plate type plasma etching equipment having an upper electrode and a lower electrode, to a plasma etching equipment having a lower electrode and a microwave-introducing window in the location facing said lower electrode, and to a method for manufacturing a semiconductor device using such a plasma etching equipment.

2. Background Art

Heretofore, as a parallel flat plate type plasma etching equipments that has an upper electrode and a lower electrode, and that can be supplied with a radio-frequency power (hereafter abbreviated as “RF”), plasma etching equipments disclosed, for example, in Japanese Patent Application Laid Open Nos. 3-170684 (Plasma Treating Method) and 8-31596 (Plasma Treating Method and Its Device) have been known.

FIG. 4 is a cross sectional view exemplifying a conventional plasma etching equipment. In FIG. 4, reference numeral 70 denotes an entire conventional plasma etching equipment, 14 denotes an upper electrode, 10 denotes a source RF that supplies RF to the upper electrode 14 through a capacitor 12, 16 denotes a wafer, 17a and 17b (insulator) denote stages for placing the wafer 16, 18 denotes a lower electrode carrying the wafer 16 through the stage 17a, 22 denotes a bias RF for supplying RF to the lower electrode 18 through a capacitor 20, 25 denotes a chamber, and 24 denotes an exhaust opening for discharging the etching gas or the like.

The above-described plasma etching equipment 70 can generate plasma of higher density than plasma generated by a plasma etching equipment of a type for supplying RF only to a lower electrode 18, which has been the mainstream, and has advantages to raise an etching rate and to improve uniformity or the like.

Separately from this, there has been known an electron cyclotron resonance (ECR) etching equipment of a type to take out plasma, generated in a generating chamber utilizing ECR, from the generating chamber by means of utilizing a generating magnetic field, and to supply RF to a sample table. In such an ECR etching equipment, a technique to supply the RF to the lower electrode efficiently by providing an electrode between the sample table and a plasma taking-out window for taking out plasma from the generating chamber is disclosed in Japanese Patent Application Laid Open No. 63-164323 (Plasma Device). On the other hand, apart from the ECR etching equipment, a conventional plasma etching equipment using microwaves has also been known. FIG. 5 is a cross sectional view exemplifying such a conventional plasma etching equipment. In FIG. 5, since the parts denoted by the same reference numerals as FIG. 4 have the same functions, description thereof will be omitted. In FIG. 5, reference numeral 80 denotes an entire conventional plasma etching equipment, and 27 denotes a microwave-guide tube for introducing microwaves.

However, in a parallel flat plate type plasma etching equipment 70 that can supply RF to both the upper electrode 14 and the lower electrode 18, since charged particles generated in the plasma generating portion can easily reach on the wafer 16, the proportion of charged particles increases comparing with radicals. As a result, there has been a problem of high probability of damages in the charge-up damage evaluation during ashing or etching.

With downsizing of devices in recent years, the dielectric constant of interlayer insulating films must be reduced. However, in above-described parallel flat plate type plasma etching equipments 70, the upper portion of a low-k film is degraded by a large quantity of ions during the etching of the low-k film, and therefore, there has been a problem of significant change in the dielectric constant of interlayer insulating films before and after etching.

On the other hand, even in a plasma etching equipment 80 different from the etching equipment using magnetic fields like the above-described ECR etching equipment, plasma etching equipments having a low probability of charge-up damage during ashing or etching have not yet been developed.

### SUMMARY OF THE INVENTION

Therefore, an object of the present invention is to solve the above-described problems, and to provide a parallel flat plate type plasma etching equipment that can supply RF to both the upper and lower electrodes, that can lower the probability of charge-up damage during ashing or etching, and that can perform processes for forming good devices without significantly changing the dielectric constant of the interlayer insulating films before and after etching; and to provide a method for manufacturing a semiconductor device using such a plasma etching equipment.

Another object of the present invention is to provide a parallel flat plate type plasma etching equipment that does not use magnetic fields and that can supply RF to the lower electrode, and having a low probability of charge-up damage during ashing or etching; and to provide a method for manufacturing a semiconductor device using such a plasma etching equipment.

According to one aspect of the present invention, in a parallel flat plate type plasma etching equipment, a radio-frequency power is supplied to each of an upper electrode and a lower electrode for mounting a wafer. The plasma etching equipment comprises a metal plate between the upper electrode and a wafer mounted on the lower electrodes. The metal plate has a ground potential, and a plurality of openings in the range of a predetermined area on the metal plate.

According to another aspect of the present invention, a plasma etching equipment comprises a lower electrode for mounting a wafer. The lower electrode is supplied with a high-frequency power. The plasma etching equipment further comprises a microwave-introducing window in the location facing the lower electrode and a metal plate provided between the microwave-introducing window and the lower electrode. The metal plate has a ground potential and a plurality of openings in the range of a predetermined area.

Other and further objects, features and advantages of the invention will appear more fully from the following description.

### BRIEF DESCRIPTION OF THE DRAWINGS

FIG. 1 is across sectional view exemplifying a plasma etching equipment according to First Embodiment of the present invention;

FIG. 2 is an enlarged sectional view showing the metal plate 31 of the plasma etching equipment 50;

FIG. 3 is a cross sectional view exemplifying a plasma etching equipment according to Second Embodiment of the present invention;

FIG. 4 is a cross sectional view exemplifying a conventional plasma etching equipment;

FIG. 5 is a cross sectional view exemplifying such a conventional plasma etching equipment.

### DETAILED DESCRIPTION OF THE PREFERRED EMBODIMENTS

The embodiments of the present invention will be described in detail referring to the drawings.

First Embodiment

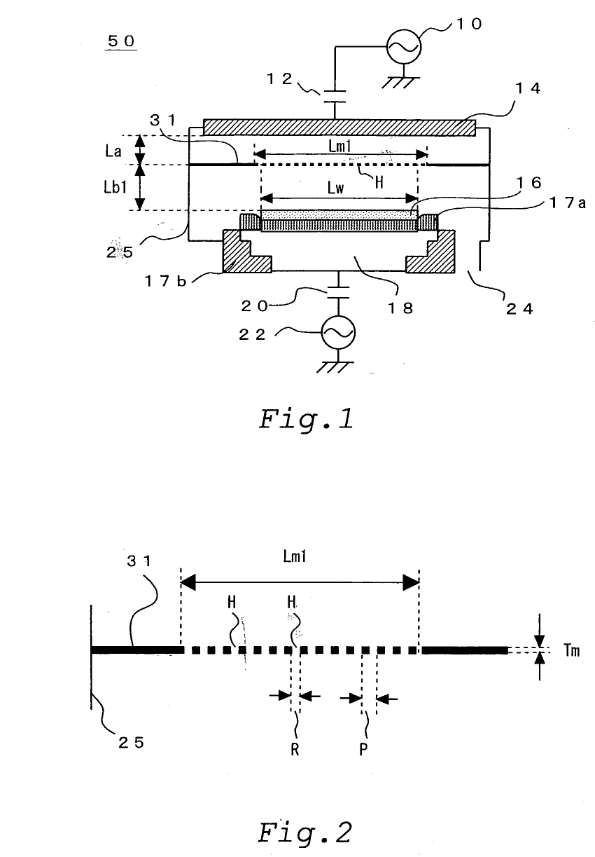

FIG. 1 is a cross sectional view exemplifying a plasma etching equipment according to First Embodiment of the present invention. In FIG. 1, reference numeral 50 denotes an entire plasma etching equipment of the present invention; 14 denotes an upper electrode; 10 denotes a source RF for supplying RF to the upper electrode 14 through a capacitor 12; 16 denotes a wafer; 17a and 17b (insulator) denote stages for placing the wafer 16; 18 denotes a lower electrode carrying the wafer 16 through the stage 17a; 22 denotes a bias RF for supplying RF to the lower electrode 18 through a capacitor 20; 25 denotes a chamber; 24 denotes an exhaust opening for discharging the etching gas or the like; and 31 denotes a metal plate provided between the upper electrode 14 and the wafer 16 mounted on the lower electrode 18, having a ground potential, and a plurality of openings H in the range of a predetermined area. However, since FIG. 1 is a cross sectional view of the plasma etching equipment 50, the predetermined area of the metal plate 31 is represented by the horizontal distance Lm1. Similarly, the area of the wafer 16 is also represented by the horizontal distance Lw.

The plasma etching equipment 50 shown in FIG. 1 is a parallel flat plate type two-frequency plasma etching equipment for a 8 inch substrate. As FIG. 1 shows, RF of 2 MHz is supplied to the lower electrode 18 carrying the wafer 16 from bias RF 22, and RF of 60 MHz is supplied to the upper electrode 14 from the source RF 10. The metal plate 31 may be placed at the location of La=30 mm from the upper electrode 14, and of Lb1=25 mm from the wafer 16 mounted on the lower electrode 18. The location is not limited thereto, but the metal plate 31 may also be movably provided between the upper electrode 14 and the wafer 16 mounted of the lower electrode 18. The metal plate 31 is fixed to the chamber 25 with metal screws (not shown), and electrically, the metal plate 31 is of the same potential (grand potential) as the chamber 25. A plurality of holes (openings) H are formed in the area of the diameter Lm1=250 mm (the range of a predetermined area) on the metal plate 31. The region of the diameter Lm1=250 mm (the range of a predetermined area) on the metal plate 31 can be larger than the area range Lw of the wafer 16.

FIG. 2 is an enlarged sectional view showing the metal plate 31 of the plasma etching equipment 50. As FIG. 2 shows, the thickness Tm of the metal plate 31 is 3 mm, and a plurality of holes H are opened in the region of a diameter Lm1=250 mm. The diameter R of each hole H is 8 mm, and the holes H are regularly opened with a pitch P of 20 mm. The metal plate 31 is made of aluminum, and the material used is A5052. The surface of the metal plate 31 is subjected to surface treatment with yttria, Y₂O₃, or aluminum oxide, Al₂O₃. Therefore, even when the surface of the metal plate 31 is sputtered by ions or charged particles in plasma, the possibility of contamination by heavy metals are minimized.

The etching of a low-k material was carried out using the above-described plasma etching equipment 50. As the low-k material, a porous organic material was used. Etching conditions were 75 mT; the radio-frequency power to the upper electrode 14 and the lower electrode 18 was 700 W and 350 W, respectively; and the flow rate of the etching gas (inert gas mixed) was 100 sccm for CF₄ and 400 sccm for Ar. The atmosphere inside the chamber 25 was discharged through the exhaust opening 24 to a predetermined degree of vacuum, and an etching gas was introduced from the inlet (not shown) between the metal plate 31 and the upper electrode 14. The inlet may be formed between the metal plate 31 and the lower electrode 18. Alternatively, the etching gas may be introduced from both of the above-described inlets.

When etching was performed using the above-described plasma etching equipment 50, the threshold value of the transistor was improved by several tens of millivolts. As a result, a significant improvement was achieved comparing with ething using a conventional plasma etching equipment. Change in the dielectric constant of the low-k film after etching was 5% or less from the dielectric constant before etching of 2.2 (F/m), which was the value that cannot be obtained from conventional plasma etching equipments.

In First Embodiment, two-frequency RF power sources 10 and 22 were used. However, the same effect can be obtained from a plasma etching equipment wherein the upper electrode 14 can be supplied two frequencies (i.e., three frequencies in total). In the example of the above description, although RF of different frequencies was supplied to the upper electrode 14 and the lower electrode 18, RF of the same frequency may also be supplied to these electrodes.

According to First Embodiment, as described above, a metal plate 31 having a ground potential, and having a plurality of openings H in the range of a predetermined area can be provided between the upper electrode 14 and the wafer 16 placed on the lower electrode 18. As a result, in a parallel flat plate type plasma etching equipment 50 which may supply RF to both the upper electrode 14 and the lower electrode 18, the probability of charge-up damage during ashing or etching can be lowered, and a plasma etching equipment 50 for processing for forming good devices without changing the dielectric constant of the interlayer insulating films before and after etching can be provided.

Second Embodiment

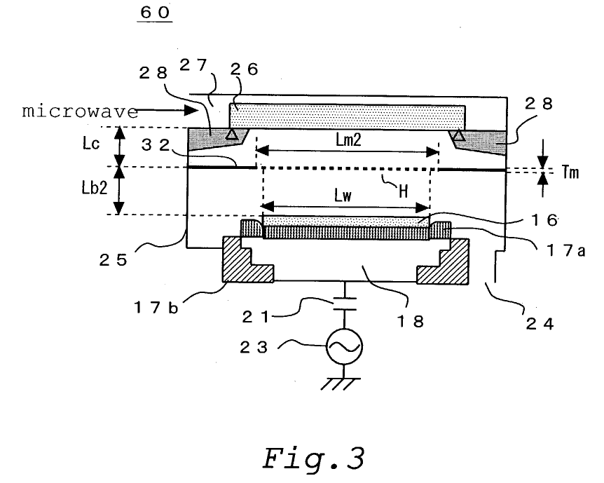

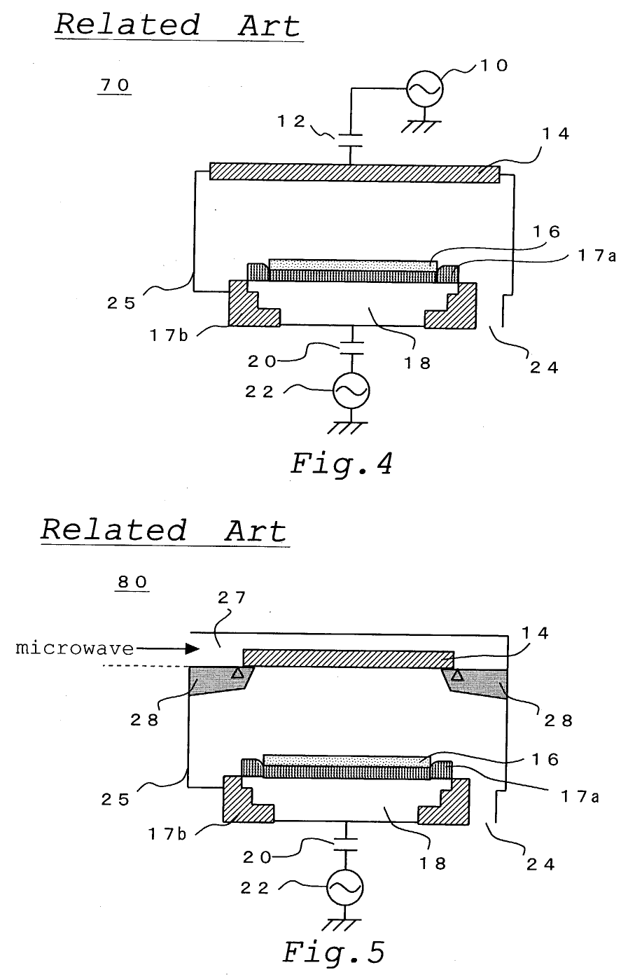

FIG. 3 is across sectional view exemplifying a plasma etching equipment according to Second Embodiment of the present invention. In FIG. 3, since the parts denoted by the same reference numerals as FIG. 1 have the same functions, no descriptions will be performed. In FIG. 3, reference numeral 60 denotes an entire plasma etching equipment of the present invention; 23 denotes a bias RF for supplying radio-frequency power to a lower electrode 18 through a capacitor 21; 26 denotes a microwave-introducing window provided in the location facing the lower electrode 18; 27 denotes a microwave wave-guide for introducing microwaves, 28 denotes an O-ring for sealing the microwave wave-introducing window 26; and 32 denotes a metal plate.

As FIG. 3 shows, in the plasma etching equipment 60, RF power is supplied only to the lower electrode 18, and the microwave-introducing window 26 is provided in the location facing the stage 17 whereon a wafer 16 is placed. The microwave-introducing window 26 is made of quartz, and also plays a role to maintain the vacuum in the chamber 25. On the atmospheric side (left side in FIG. 3) of the microwave-introducing window 26 (quartz plate), a microwave wave-guide 27 for propagating microwaves is formed. Since microwaves are evenly introduced through the microwave-introducing window 26 into the chamber 25, a slit antenna (not shown) or a dielectric line (not shown) can be used on the microwave-introducing window 26.

The metal plate 32 can be installed at the location of Lc=30 mm from the microwave-introducing window 26 (quartz plate), and of Lb2=40 mm from the wafer 16 placed on the lower electrode 18. The location is not limited thereto, but the metal plate 32 may also be movably provided between the microwave-introducing window 26 and the wafer 16 mounted of the lower electrode 18. The metal plate 32 is fixed to the chamber 25 with metal screws (not shown), and electrically, the metal plate 32 is of the same potential (grand potential) as the chamber 25. A plurality of holes (openings) H are formed in the area of the diameter Lm2=220 mm (the range of a predetermined area) on the metal plate 32. The region of the diameter Lm2=220 mm (the range of a predetermined area) on the metal plate 32 can be larger than the area range Lw of the wafer 16. Substantially the same as the metal plate 31 of First Embodiment (refer to FIG. 2), the thickness Tm of the metal plate 32 is 3 mm, and a plurality of holes H are opened in the region of a diameter Lm2=220 mm. The diameter R of each hole H is 5 mm, and the holes H are regularly opened with a pitch P of 7 mm. The metal plate 32 is also made of aluminum, and the material used is A5052. The surface of the metal plate 32 is subjected to alumite treatment with yttria, Y₂O₃, or aluminum oxide, Al₂O₃. Therefore, even when the surface of the metal plate 32 is sputtered by ions or charged particles in plasma, the possibility of contamination by heavy metals are minimized.

The ashing of a low-k material was carried out using the above-described plasma etching equipment 60. As the low-k material, a porous organic material was used. As etching conditions, the flow rate of the etching gas (inert gas mixed) was 100 sccm for N₂ and 10 sccm for H₂; the microwave power was 2 kW; the RF power to the lower electrode 18 was 300W. The atmosphere inside the chamber 25 was discharged through the exhaust opening 24 to a predetermined degree of vacuum, and an etching gas was introduced from the inlet (not shown) between the metal plate 32 and the microwave-introducing window 26. The inlet may be formed between the metal plate 32 and the lower electrode 18. The pressure was 5 Pa.

When ashing was performed using the above-described plasma etching equipment 60, the threshold value of the transistor was improved by several tens of millivolts. As a result, a significant improvement was achieved comparing with ething using a conventional plasma etching equipment. Change in the dielectric constant of the low-k film after ashing was 5% or less from the dielectric constant before etching of 2.2 (F/m), which was the value that cannot be obtained from conventional plasma etching equipments.

In Second Embodiment, a constitution for generating plasma by supplying microwaves through a microwave-introducing window 26 (quartz plate) installed in the upper portion of the chamber 25. However, a method wherein plasma is generated using microwaves in a separate place, and the plasma is introduced above or below the inserted metal plate 32 may also be used. The metal plate 32 (or 31) may also be movably installed between the upper electrode 14 and the wafer 16 placed on the lower electrode 18, after the wafer 16 is set on the stage 17 at the optimal position for the process.

Although it is not shown in the above-described embodiments, there may be cases where etching is performed with a plasma etching equipment 50 or 60 of the present invention using a gas that forms a fluorocarbon film, such as CF₄, CHF₃, CH₂F₂, C₄F₈, and C₅F₈. In these cases, by taking out the wafer after etching of a wafer is completed, and discharging the oxygen plasma for several tens of seconds until the next wafer is carried in, the film deposited on the surface of the metal plate 31 or 32 of the upper electrode 14 side or the microwave-introducing window 26 side due to the advance of the etching process can be removed completely.

According to Second Embodiment, as described above, in a plasma etching equipment supplying RF to the lower electrode, microwaves can be used, and a metal plate 32 having a ground potential, and having a plurality of openings H in the range of a predetermined area can be installed between the microwave-introducing window 26 and the wafer 16 placed on the lower electrode 18. As a result, a plasma etching equipment 60 having a low probability of charge-up damage during ashing or etching can be provided.

The features and the advantages of the present invention as described above may be summarized as follows.

According to one aspect of the present invention, in a plasma etching equipment, a metal plate having a ground potential, and having a plurality of openings H in the range of a predetermined area can be installed between the upper electrode and the wafer placed on the lower electrode. Accordingly, in a parallel flat plate type plasma etching equipment that can supply RF to both the upper electrode and the lower electrode, the probability of charge-up damage during ashing or etching can be lowered, and a plasma etching equipment for processing for forming good devices without changing the dielectric constant of the interlayer insulating films before and after etching can be provided.

In another aspect, in a plasma etching equipment supplying RF to the lower electrode, microwaves can be used, and a metal plate having a ground potential, and having a plurality of openings H in the range of a predetermined area can be installed between the microwave-introducing window and the wafer placed on the lower electrode. Accordingly, a plasma etching equipment having a low probability of charge-up damage during ashing or etching can be provided.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-146828, filed on May 21, 2002 including specification, claims, drawings and summary, on which the Convention priority of the present application is based, are incorporated herein by reference in its entirety.

1. A parallel flat plate type plasma etching equipment wherein a radio-frequency power is supplied to each of an upper electrode, and a lower electrode for mounting a wafer; said plasma etching equipment comprising a metal plate between said upper electrode and a wafer mounted on said lower electrodes, said metal plate having a ground potential, and a plurality of openings in the range of a predetermined area on said metal plate.

2. The plasma etching equipment according to claim 1, wherein said range of a predetermined area of said metal plate is larger than the area of said wafer.

3. The plasma etching equipment according to claim 1, further comprising an inlet of an etching gas for forming plasma, between said metal plate and said upper electrode, or between said metal plate and said lower electrode.

4. The plasma etching equipment according to claim 1, wherein said metal plate is movably mounted between a wafer mounted on said upper electrode and a wafer mounted on said lower electrode.

5. The plasma etching equipment according to claim 1, wherein said metal plate is subjected to the surface treatment with yttria, Y₂O₃, or aluminum oxide, Al₂O₃.

6. A method for manufacturing a semiconductor device using the plasma etching equipment according to claim 1.

7. A plasma etching equipment comprising;
a lower electrode, supplied with a high-frequency power, for mounting a wafer;
a microwave-introducing window in the location facing said lower electrode; and
a metal plate provided between said microwave-introducing window and said lower electrode, said metal plate having a ground potential and a plurality of openings in the range of a predetermined area.

8. The plasma etching equipment according to claim 7, wherein said range of a predetermined area of said metal plate is larger than the area of said wafer.

9. The plasma etching equipment according to claim 7, further comprising an inlet of an etching gas for forming plasma, between said metal plate and said microwave-introducing window, or between said metal plate and said lower electrode.

10. The plasma etching equipment according to claim 7, wherein said metal plate is movably mounted between a wafer mounted on said microwave-introducing window and a wafer mounted on said lower electrode.

11. The plasma etching equipment according to claim 7, wherein said metal plate is subjected to the surface treatment with yttria, Y₂O₃, or aluminum oxide, Al₂O₃.

12. A method for manufacturing a semiconductor device using the plasma etching equipment according to claim 7.
